(19) United States
(12) Patent Application Publication
(10) Pub. No.: US 2026/0164905 A1
(43) Pub. Date: Jun. 11, 2026

(54) VERTICAL STACKED MICRODISPLAY PANEL AND MANUFACTURING METHOD THEREOF

(71) Applicant: WAVELORD CO., LTD, Hwaseong-si (KR)

(72) Inventors: Juneo SONG, Suwon-si (KR); Ji Hyung MOON, Gunpo-si (KR); Tae Kyoung KIM, Osan-si (KR)

(73) Assignee: WAVELORD CO., LTD, Hwaseong-si (KR)

(21) Appl. No.: 19/333,452

(22) Filed: Sep. 19, 2025

(30) Foreign Application Priority Data
Dec. 3, 2024 (KR) 10-2024-0177194
Mar. 4, 2025 (KR) 10-2025-0027424

(51) Int. Cl. H10H 29/856; H10H 29/01; H10H 29/24

(52) U.S. Cl. CPC H10H 29/856; H10H 29/0363; H10H 29/24

(57) ABSTRACT

The present invention relates to a vertically stacked microdisplay panel, and the vertically stacked microdisplay panel includes a back wafer having a plurality of complementary metal-oxide semiconductor (CMOS) electrode pads aligned on an upper surface, a plurality of light-emitting diode (LED) stacks each including a plurality of light-emitting portions stacked in a vertical direction through a bonding layer, and respectively aligned on the plurality of CMOS electrode pads, and a common electrode formed on the plurality of LED stacks, wherein each of the plurality of LED stacks has a short passage formed in a partial region so that a current flows through the light-emitting portion where the short passage is not formed, and only a specific color is emitted, and a reflective layer is disposed between the light-emitting portion and the CMOS electrode pad. According to the present invention, optical loss due to CMOS electrode pads in a vertically stacked tandem structure can be significantly improved.

### CROSS-REFERENCE TO RELATED APPLICATION

This application claims priority to and the benefit of Korean Patent Application No. 10-2025-0027424, filed on Mar. 4, 2025, the disclosure of which is incorporated herein by reference in its entirety.

### BACKGROUND

### Field of the Invention

The present invention relates to a vertically stacked microdisplay panel and a method of manufacturing the same, and more particularly, to a vertically stacked light-emitting diode on silicon (LEDOS) microdisplay panel in which the need for an alignment process of LED stacks and complementary metal-oxide semiconductor (CMOS) electrode pads is eliminated by using an engineering monolithic epitaxy wafer method, and a method of manufacturing the same.

### Discussion of Related Art

The types of implementation of the metaverse, which has recently been attracting attention, are classified into four types such as virtual reality (VR), augmented reality (AR), mixed reality (MR), and extended reality (XR). It is expected that the metaverse ecosystem will develop in the future, focusing on XR, which is a reality that combines VR, AR, and MR among the four types. In addition, in order to implement this effectively, devices (for example, smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a conventional microdisplay panel 10 corresponds to a technology that combines a Si CMOS semiconductor wafer process and a high-resolution, high-brightness, ultra-small display process, and the conventional microdisplay panel 10 may have a structure in which a Si CMOS wafer 11 that has a (100) crystal plane of 4″ or more and is provided with a plurality of CMOS electrode pads 12, a plurality of microLED electrode pads 14, and a transparent wafer 13 of 4″ or more that is provided with a plurality of microLED chips 15 are bonded through a conductive bond 16. Meanwhile, the types of microdisplay panels expected to be applied to XR devices include liquid crystal (LC)-based LC on Si (LCOS), organic light-emitting diode (OLED)-based OLED on Si (OLEDOS), and LED on Si (LEDOS) based on ultra-small microLEDs with pixel sizes of less than 5 μm. In addition, in the case of VR where displays with a low pixel density are applied, the microdisplay panels are being developed and mass-produced mainly based on LCOS and OLEDOS.

However, with the advancement of metaverse implementation technology, the need for lightweight AR, MR, and XR devices to which microdisplay panels with a high pixel density are applied is gradually increasing. In addition, although the development of LEDOS technology, which is considered an ideal solution in theory based on its superior inorganic properties, is urgently needed to satisfy these needs, a microdisplay panel platform for this has not yet been established.

LEDOSs based on ultra-small microLEDs with pixel sizes of less than 5 μm have the advantages of an excellent power-to-performance ratio (P/P) and a short response speed when applied to XR devices, and since the LEDoSs are composed of inorganic materials, there are the advantages that the LEDoSs have a long lifespan, and have efficient power use to reduce heat generation and enable long-term battery life. Particularly, since XR devices have a very short distance between the display and the eyes, even a slight delay in image conversion can easily cause discomfort such as dizziness. Thus, LEDOS, which has a nanosecond response speed, is considered to be the most suitable for XR devices compared to LCOS and OLEDOS, which have a microsecond response speed.

Furthermore, it is evaluated that the biggest reason why LEDOS is attracting attention in AR, MR, and XR devices, unlike VR, is due to its brightness and light-emitting efficiency. Since smart glasses can be worn regardless of location, high brightness is essential for normal operation even in outdoor environments such as sunlight. In theory, microLEDs support brightness of tens to millions of nits, and since OLEDs are made of organic materials, whereas microLEDs are made of inorganic materials, the microLEDs also have the advantage of high light-emitting efficiency.

However, despite the above-described advantages, the biggest reason why LEDoSs based on ultra-small microLEDs with pixel sizes of less than 5 μm have not established as a major component of XR devices is the difficulty in mass production. In other words, LEDOS requires millions of ultra-small microLEDs to be fixed on a Si CMOS wafer so that the process difficulty is high and the yield is very low, which leads to increased manufacturing costs and high component prices. This is reflected in the final consumer price, and it is difficult to satisfy market demand as LEDOS is supplied as a high-priced XR device.

Meanwhile, as shown in FIG. 2, the development of LEDOS to which group III-V compound (GaN, GaP, and the like) microLED light sources are applied has been in progress until recently through traditional approaches such as (1) monolithic integration of wafers (or unit dies) composed of microLED arrays on CMOS wafers or (2) hybridization between wafers (or unit dies) on blue, green, and red light source wafers (or unit dies) on which CMOS wafers or microLED arrays are fabricated.

One of the biggest obstacles to the development of LEDOS to which blue, green, and red microLED light sources composed of group III-V compounds to date are applied is the difficulty in securing a solution for pixels of less than 5 μm. In addition, recently, 5 μm-level pixels have been successfully demonstrated using monolithic integration technology, and some demonstrators developed based on hybridization technology were fabricated using sapphire flip chips, achieving pixels of the 10 μm-level pixels. Additionally, it has been demonstrated that it is possible to reduce pixels to the 5 μm level in the same way by using micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer composed of a group III-V compound microLED array and a Si CMOS back plane wafer composed of numerous IC electrode pad arrays, and then assembling them. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDOS to which high-resolution, high-brightness, and high-speed driving blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using conventional engineering monolithic epitaxy wafers using metal bonding, the patterning etching process faces even greater difficulties.

As another example, great progress has been made in solving the problem of limitations in the brightness and resolution of LEDOS to which group III-V compound microLED light sources are recently applied, and a novel engineered monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED fab process in the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in step (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in step (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in step (2), there is a problem that defects occur due to the difficulty in ultra-fine alignment wafer bonding between the Si blanket wafer (that is, front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 ratio.

That is, although the engineering monolithic epitaxy wafer approach presented in the above-described technologies is evaluated to provide a solution that brings us one step closer to the implementation of LEDOS based on ultra-small microLEDs with pixel sizes of less than 5 μm, since there are quality and yield issues caused by the use of metals (low temperature, multi-layer) in wafer bonding, and it is very difficult to manufacture high-resolution microdisplays with ultra-fine pixels of less than 3 μm, and there are also problems with some alignment processes, new alternatives are needed.

In addition, since the conventional vertically stacked tandem structure of the microdisplays still uses a color filter to implement full color, there are disadvantages in terms of color quality, process complexity, and productivity.

Meanwhile, a CMOS electrode pad 141 in a conventional microdisplay panel structure having a short passage as shown in FIG. 4 is generally formed by a method such as depositing or plating copper (Cu). However, copper has a high light absorption rate in the green wavelength range or blue wavelength range, which causes a problem in that the light-emitting efficiency of green and blue colors is reduced. Accordingly, there is a need for a method to improve optical loss due to the CMOS electrode pads 141 in a vertically stacked microdisplay panel structure.

### RELATED ART DOCUMENT

### Patent Document

(Patent Document 0001) Korea Patent Publication No. 10-2018-0009116

### SUMMARY OF THE INVENTION

The present invention is directed to solving the above-described conventional problems and providing a vertically stacked light-emitting diode on silicon (LEDOS) microdisplay panel which can improve optical loss due to CMOS electrode pads in a vertically stacked tandem structure while eliminating the need for an alignment process of LED stacks and CMOS electrode pads by using an engineering monolithic epitaxy wafer method, and a method of manufacturing the same.

According to the present invention, there is provided a vertically stacked microdisplay panel including a back wafer having a plurality of CMOS electrode pads aligned on an upper surface, a plurality of LED stacks each including a plurality of light-emitting portions stacked in a vertical direction through a bonding layer, and respectively aligned on the plurality of CMOS electrode pads, a common electrode formed on the plurality of LED stacks, wherein each of the plurality of LED stacks has a short passage formed in a partial region so that a current flows through the light-emitting portion where the short passage is not formed, and only a specific color is emitted, and a reflective layer is disposed between the light-emitting portion and the CMOS electrode pad.

Also, the reflective layer may be formed of a non-conductive reflector.

Furthermore, the short passage may be formed to pass through the reflective layer.

In addition, the common electrode may be a positive electrode or a negative electrode.

According to the present invention, there is provided a method of manufacturing a vertically stacked microdisplay panel including a preparation step of preparing a plurality of front wafers including a support wafer and light-emitting portions, and a back wafer having a plurality of CMOS electrode pads aligned on an upper surface, a stacking step of vertically stacking the plurality of light-emitting portions on the support wafer by repeatedly bonding another front wafer on one front wafer through a bonding layer and then removing the support wafer of the other front wafer, a first processing step of forming a reflective layer on one side of the plurality of stacked light-emitting portions, and then forming a first short passage in a partial region from one side of the reflective layer, a bonding step of bonding the plurality of stacked light-emitting portions to the back wafer, and then removing the support wafer to stack the plurality of light-emitting portions on the back wafer, a second processing step of forming a second short passage in a partial region from the other side of the plurality of stacked light-emitting portions, an etching step of etching the plurality of stacked light-emitting portions and separating the plurality of stacked light-emitting portions into preset units, thereby allowing the plurality of LED stacks to be respectively aligned on the plurality of CMOS electrode pads, and a forming step of forming a common electrode on the plurality of LED stacks, wherein each of the plurality of LED stacks has a short passage formed in a partial region so that a current flows through the light-emitting portion where the short passage is not formed, and only a specific color is emitted, and the reflective layer is disposed between the light-emitting portion and the CMOS electrode pad.

Also, the reflective layer may be formed of a non-conductive reflector.

Furthermore, the first short passage may be formed to pass through the reflective layer.

In addition, the common electrode may be a positive electrode or a negative electrode.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a conventional microdisplay panel;

FIG. 2 shows a conventional light-emitting diode on silicon (LEDOS) development approach;

FIG. 3 shows an approach using a conventional engineering monolithic epitaxy wafer;

FIG. 4 shows blue light or green light that is absorbed by complementary metal-oxide semiconductor (CMOS) electrode pads in a conventional microdisplay panel structure provided with a short passage;

FIG. 5 is a flowchart for describing a method of manufacturing a vertically stacked microdisplay panel according to one embodiment of the present invention;

FIG. 6 shows a process of preparing a front wafer in a p-side up form in the method of manufacturing a vertically stacked microdisplay panel according to one embodiment of the present invention;

FIG. 7 shows a process of preparing a front wafer in an n-side up form in the method of manufacturing a vertically stacked microdisplay panel according to one embodiment of the present invention;

FIG. 8 shows a process of preparing a back wafer in the method of manufacturing a vertically stacked microdisplay panel according to one embodiment of the present invention;

FIGS. 9 and 10 show a process of manufacturing a vertically stacked microdisplay panel according to the method of manufacturing a vertically stacked microdisplay panel according to one embodiment of the present invention; and

FIGS. 11 and 12 show a vertically stacked microdisplay panel according to one embodiment of the present invention.

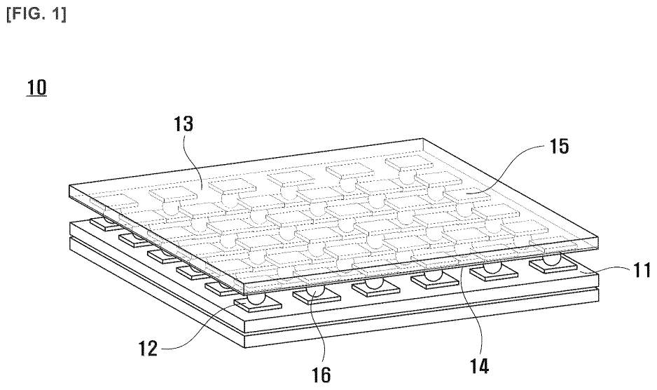

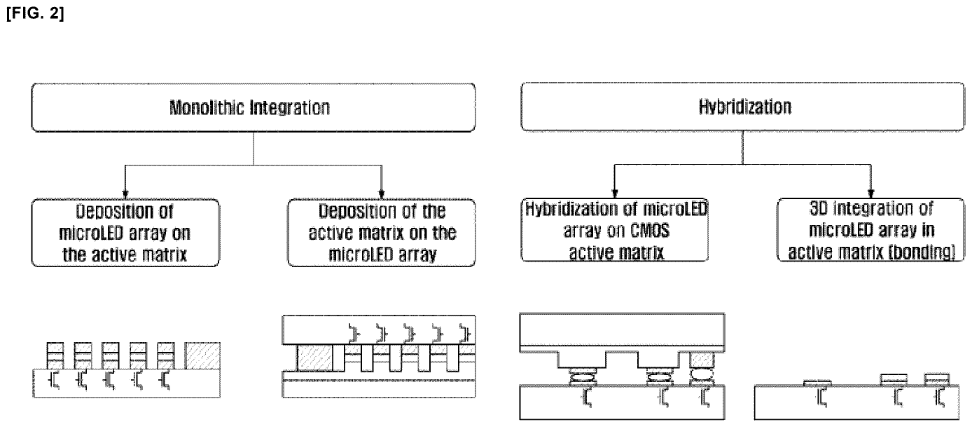

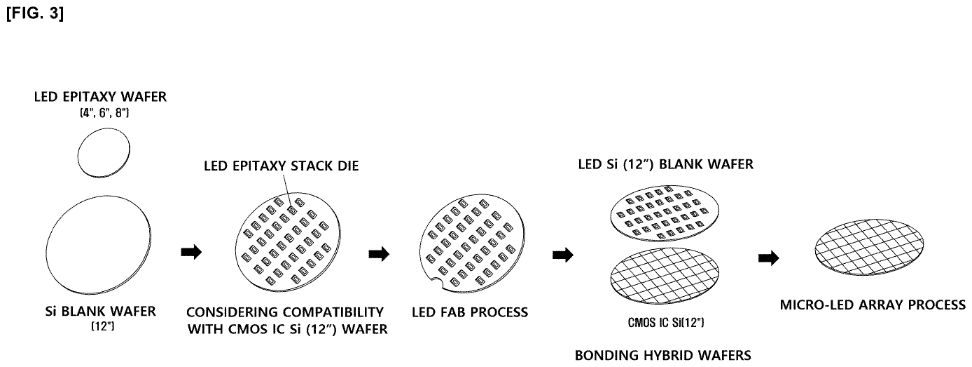

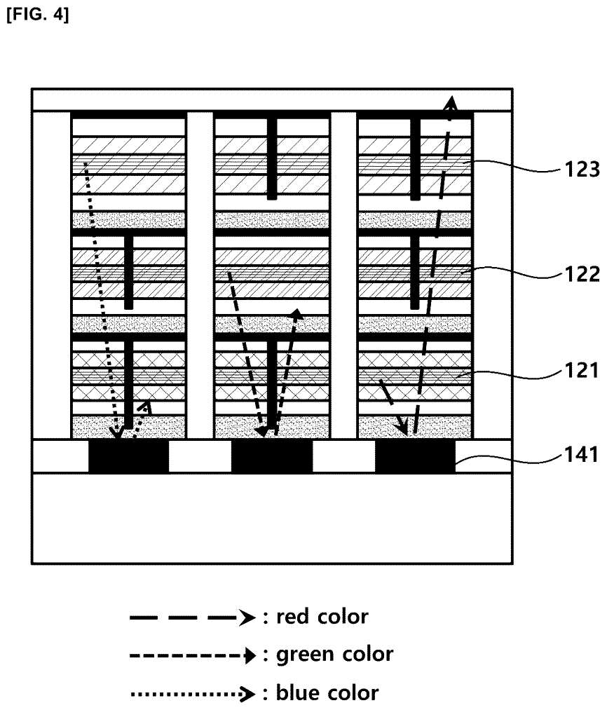

### DETAILED DESCRIPTION OF EXEMPLARY EMBODIMENTS

Hereinafter, some embodiments of the present invention will be described in detail through exemplary drawings. When assigning reference numerals to components of each of the drawings, it should be noted that identical components are denoted by the same reference numerals as much as possible even when they are shown on different drawings.

In addition, when describing embodiments of the present invention, when a detailed description of a related known configuration or function is determined to hinder understanding of the embodiment of the present invention, the detailed description is omitted.

Additionally, when describing components of embodiments of the present invention, terms such as first, second, A, B, (a), (b), and the like may be used. These terms are only intended to distinguish the components from other components, and the nature, order, or sequence of the components are not limited by the terms.

Hereinafter, a method S100 of manufacturing a vertically stacked microdisplay panel according to one embodiment of the present invention will be described in detail with reference to the attached drawings.

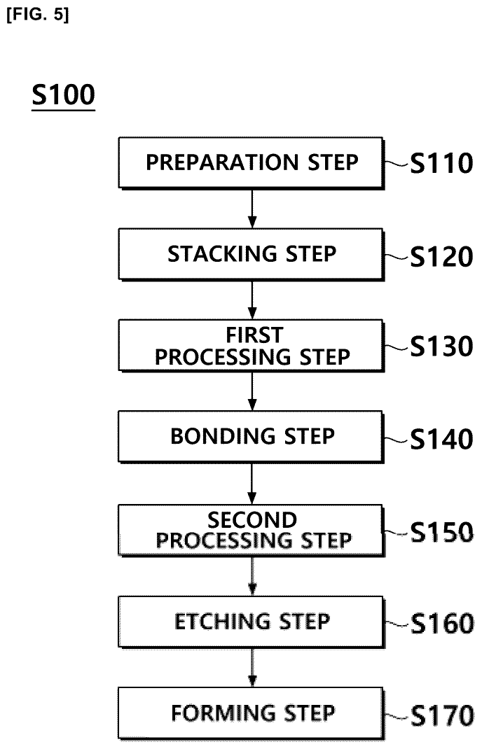

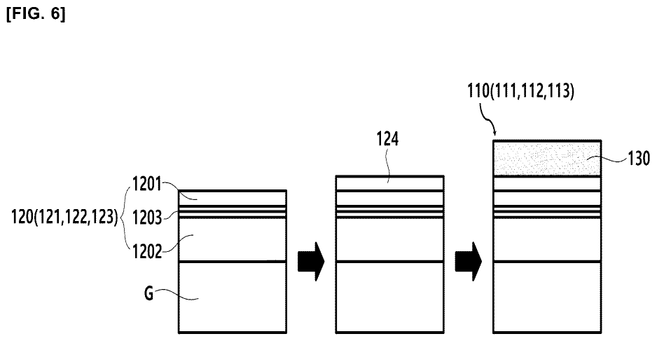

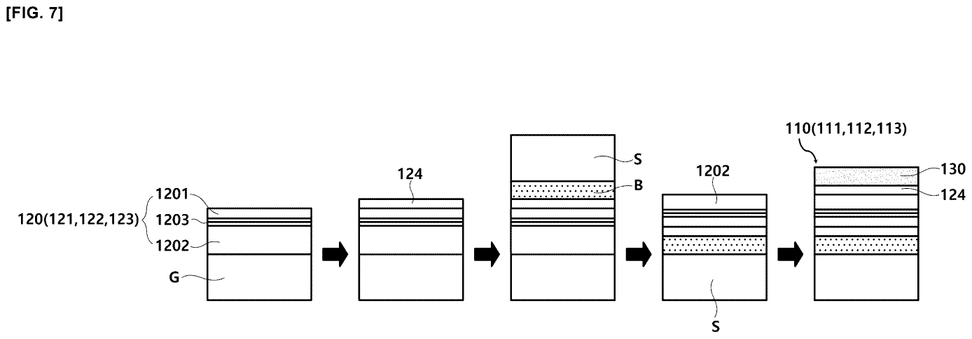

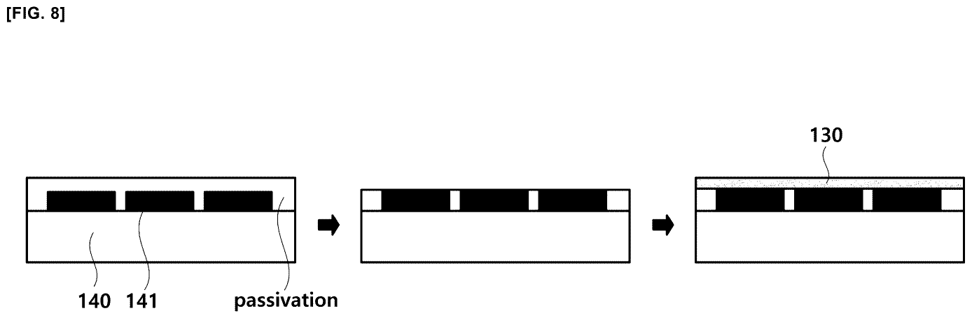

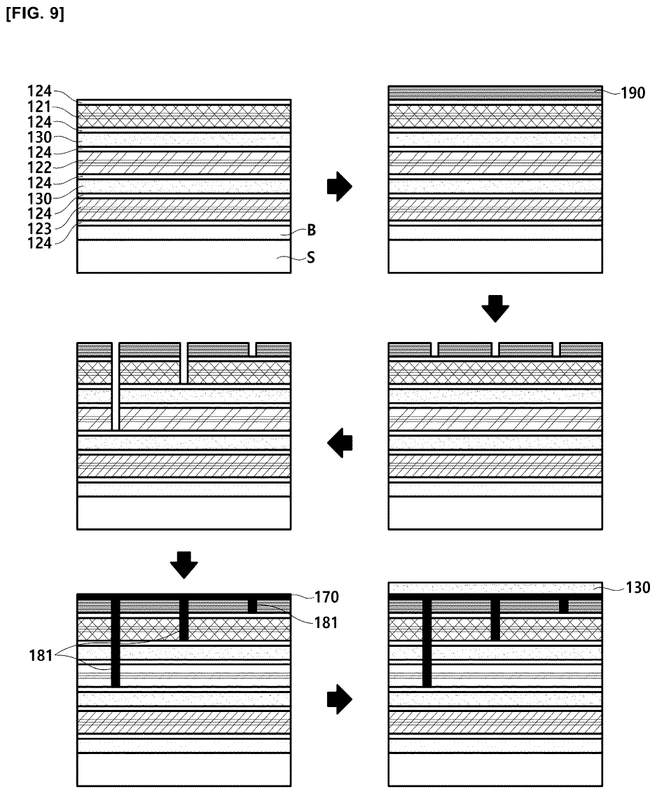

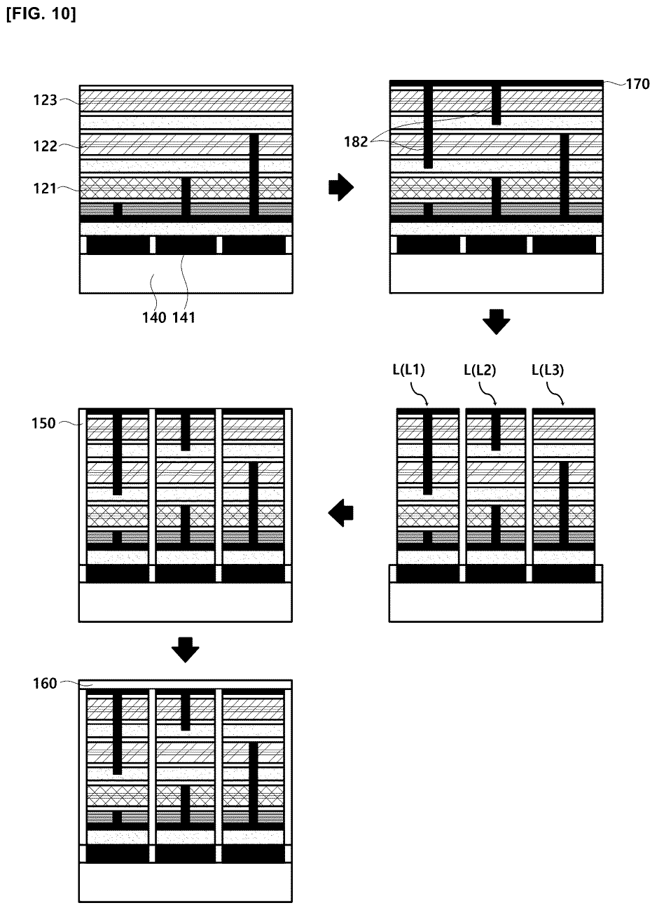

FIG. 5 is a flowchart for describing a method of manufacturing a vertically stacked microdisplay panel according to one embodiment of the present invention, FIG. 6 shows a process of preparing a front wafer having a p-side up form in the method of manufacturing a vertically stacked microdisplay panel according to one embodiment of the present invention, FIG. 7 shows a process of preparing a front wafer having an n-side up form in the method of manufacturing a vertically stacked microdisplay panel according to one embodiment of the present invention, FIG. 8 shows a process of preparing a back wafer in the method of manufacturing a vertically stacked microdisplay panel according to one embodiment of the present invention, and FIGS. 9 and 10 show a process of manufacturing a vertically stacked microdisplay panel according to the method of manufacturing a vertically stacked micro-display panel according to one embodiment of the present invention.

As shown in FIGS. 5 to 10, the method S100 of manufacturing a vertically stacked microdisplay panel according to one embodiment of the present invention may include a preparation step S110, a stacking step S120, a first processing step S130, a bonding step S140, a second processing step S150, an etching step S160, and a forming step S170.

The preparation step S110 is a step of preparing a plurality of front wafers 110 and a back wafer 140.

The plurality of front wafers 110 are each for emitting different colors, and the plurality of front wafers 110 may include a first front wafer 111 for emitting a first color, a second front wafer 112 for emitting a second color different from the first color, and a third front wafer 113 for emitting a third color different from the first and second colors. Meanwhile, the first color, the second color, and the third color may be, for example, red, green, and blue, respectively, but are not limited thereto, and may include various other colors.

Here, the first front wafer 111 may include a support wafer S and a first light-emitting portion 121 disposed on an upper portion of the support wafer S, the second front wafer 112 may include the support wafer S and a second light-emitting portion 122 disposed on an upper portion of the support wafer S, and the third front wafer 113 may include the support wafer S and a third light-emitting portion 123 disposed on an upper portion of the support wafer S.

A light-emitting portion 120 generates light and may emit blue light, green light, or red light. In the present invention, when the light-emitting portion 120 emits blue light or green light, binary, ternary, or quaternary compounds such as InN, InGaN, GaN, AlGaN, AlN, and AlGaInN, which are group III (Al, Ga, and In) nitride semiconductors among group III-V compound semiconductors, may be disposed in an appropriate position and order on an initial growth wafer G and epitaxially grown.

Particularly, in order to emit blue or green light, a high-quality group III nitride semiconductor such as InGaN with a high In composition needs to be preferentially formed on an upper portion of a group III nitride semiconductor composed of GaN, AlGaN, AlN, or AlGaInN, but is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are group III (Al, Ga, and In) phosphide semiconductors among group III-V compound semiconductors, may be disposed in an appropriate position and order on the initial growth wafer G and epitaxially grown. In addition, in recent years, in order to further improve the development of device and process technology and the value of display panel products, in the case of emitting red light, a high-quality group III nitride semiconductor such as InGaN with a high In composition of 30% or more, other than a group III phosphide semiconductor, may be preferentially formed on an upper portion of a group III nitride semiconductor composed of GaN, AlGaN, AIN, or AlGaInN.

Particularly, in order to emit red light, a high-quality group III phosphide semiconductor such as InGaP having a high In composition needs to be preferentially formed on an upper portion of a group III phosphide semiconductor composed of GaP, AlInP, AlGaP, AIP, AlGaInP, but is not limited thereto, and the group III nitride semiconductor is used as a basis for the description below.

More specifically, each of the light-emitting portions 120 may include a first semiconductor region 1201 (for example, a p-type semiconductor region), an active region 1203 (for example, multi quantum wells, MQWs), and a second semiconductor region 1202 (for example, an n-type semiconductor region), have a structure in which the second semiconductor region 1202, the active region 1203, and the first semiconductor region 1201 are sequentially epitaxially grown on the growth wafer G, and ultimately have an overall thickness of about 5.0 to 8.0 μm typically including a plurality of multi-layers of group III nitrides, but is not limited thereto.

Each of the first semiconductor region 1201, the active region 1203, and the second semiconductor region 1202 may be formed as a single layer or plurality of layers. In addition, although not shown, before epitaxially growing the light-emitting portion 120 on an upper portion of the growth wafer G, necessary layers such as a buffer layer may be added to improve the quality of the epitaxially grown light-emitting portion 120. For example, the buffer layer may be configured to have a thickness of typically around 4.0 μm, including a nucleation layer NL and a compliant layer CL composed of an undoped semiconductor region to relieve stress and improve thin film quality. Additionally, when the growth wafer G is removed using a laser lift off (LLO) technique, a sacrificial layer SL may be provided between the nucleation layer and the undoped semiconductor region, and a seed layer may also function as the sacrificial layer.

The second semiconductor region 1202 has a second conductivity and may be formed on the growth wafer G. The second semiconductor region 1202 may have a thickness of 2.0 to 3.5 μm.

The active region 1203 generates light by utilizing the recombination of electrons and holes and may be formed on the second semiconductor region 1202. The active region 1203 may have a thickness of several tens of nm in a plurality of layers.

The first semiconductor region 1201 has a first conductivity (p-type) and may be formed on the active region 1203. The first semiconductor region 1201 may have a thickness of several tens of nm to several um in a plurality of layers, and the surface may have gallium polarity (Ga-polarity).

That is, the active region 1203 may be disposed between the first semiconductor region 1201 and the second semiconductor region 1202, and when holes in the first semiconductor region 1201, which is a p-type semiconductor region, and electrons in the second semiconductor region 1202, which is an n-type semiconductor region, recombine in the active region 1203, light may be generated.

Additionally, in the process of preparing the front wafer 110, an optically transparent and electrically conductive ohmic contact electrode 124 that is electrically connected to the light-emitting portion 120 by making ohmic contact with the light-emitting portion 120 may be formed on at least one of upper and lower surfaces of the light-emitting portion 120, which will be described below.

The support wafer S supports the light-emitting portion 120 (first light-emitting portion 121, second light-emitting portion 122, or third light-emitting portion 123) disposed on an upper portion. When an initial growth wafer G is not removed, the growth wafer G may be the support wafer S, which is a separate wafer bonded to remove the initial growth wafer G.

FIG. 6 shows a process of preparing a front wafer 110 in a p-side up form in the method of manufacturing a vertically stacked microdisplay panel according to one embodiment of the present invention.

As shown in FIG. 6, the process of preparing the first front wafer 111 in a p-side up form is as follows.

For the first front wafer 111 for emitting red light, a front wafer 110 in a p-side up form is prepared by sequentially epitaxially growing a second semiconductor region 1202, an active region 1203, and a first semiconductor region 1201 on a GaAs growth wafer G, forming a p-type ohmic contact electrode 124 having transparent conductivity on an upper surface of the first semiconductor region 1201, and then depositing and forming a bonding layer 130 having transparent conductivity on the ohmic contact electrode 124. In this case, the growth wafer G serves as a support wafer S, and the first front wafer 111 may have a structure in which the support wafer S, the light-emitting portion 120, the ohmic contact electrode 124, and the bonding layer 130 are sequentially stacked.

In addition, the process of preparing the second front wafer 112 or the third front wafer 113 in a p-side up form is as follows.

For the second front wafer 112 for emitting green light or the third front wafer 113 for emitting blue light, a front wafer 110 in a p-side up form is prepared by sequentially epitaxially growing a second semiconductor region 1202, an active region 1203, and a first semiconductor region 1201 on a sapphire (α-phase Al2O3) growth wafer G, forming a p-type ohmic contact electrode 124 having transparent conductivity on an upper surface of the first semiconductor region 1201, and then depositing and forming a bonding layer 130 having transparent conductivity on an ohmic contact electrode 124. In this case, the growth wafer G serves as a support wafer S, and the second front wafer 112 may have a structure in which the support wafer S, the light-emitting portion 120, the ohmic contact electrode 124, and the bonding layer 130 are sequentially stacked.

Meanwhile, in the case of green light and blue light, a blue or green light-emitting portion 120 may be formed on a Si growth wafer G having a (111) crystal plane instead of the sapphire (α-phase Al2O3) growth wafer G, and in this case, the Si growth wafer G may be separated and removed by a mechanical polishing technique or a chemical etching technique (chemical lift off, CLO).

FIG. 7 shows a process of preparing a front wafer 110 in an n-side up form in the method of manufacturing a vertically stacked microdisplay panel according to one embodiment of the present invention.

As shown in FIG. 7, the process of preparing the first front wafer 111 in an n-side up form is as follows.

For the first front wafer 111 for emitting red light, after sequentially epitaxially growing a second semiconductor region 1202, an active region 1203, and a first semiconductor region 1201 on a GaAs growth wafer G, a p-type ohmic contact electrode 124 having transparent conductivity may be formed on an upper surface of the first semiconductor region 1201, and then a support wafer S and the ohmic contact electrode 124 may be bonded through a bonding layer B. Afterward, the growth wafer G may be separated from the light-emitting portion 120 using a chemical lift off (CLO) technique, the second semiconductor region 1202 may be etched to reduce the thickness of the second semiconductor region 1202, and then an n-type ohmic contact electrode 124 having transparent conductivity may be formed on a surface of the second semiconductor region 1202 whose thickness is reduced, and a bonding layer 130 may be deposited and formed on the n-type ohmic contact electrode 124, thereby preparing the front wafer 110 in an n-side up form. In this case, the support wafer S may be formed of a Si material having a (111), (110) or (100) crystal plane, but is not limited thereto, and the first front wafer 111 may have a structure in which the support wafer S, the bonding layer B, the ohmic contact electrode 124, the light-emitting portion 120, the ohmic contact electrode 124, and the bonding layer 130 are sequentially stacked.

In addition, the process of preparing the second front wafer 112 or the third front wafer 113 in an n-side up form is as follows.

For the second front wafer 112 for emitting green light or the third front wafer 113 for emitting blue light, after sequentially epitaxially growing a second semiconductor region 1202, an active region 1203, and a first semiconductor region 1201 on a sapphire (α-phase Al2O3) growth wafer G, a p-type ohmic contact electrode 124 having transparent conductivity is formed on an upper surface of the first semiconductor region 1201, and then a support wafer S and the ohmic contact electrode 124 are bonded through a bonding layer B. Afterward, the growth wafer G may be separated from the light-emitting portion 120 using a laser lift off (LLO) technique, the second semiconductor region 1202 may be etched to reduce the thickness of the second semiconductor region 1202, and then an n-type ohmic contact electrode 124 having transparent conductivity is formed on the surface of the second semiconductor region 1202 whose thickness has been reduced, and a bonding layer 130 is deposited and formed on the n-type ohmic contact electrode 124, thereby preparing the front wafer 110 in an n-side up form. In this case, the support wafer S may be formed of a Si material having a (111), (110) or (100) crystal plane, but is not limited thereto, and the second front wafer 112 may have a structure in which the support wafer S, the bonding layer B, the ohmic contact electrode 124, the light-emitting portion 120, the ohmic contact electrode 124, and the bonding layer 130 are sequentially stacked.

Furthermore, in the present invention, the materials of the growth wafer G and/or the support wafer S may each be silicon (Si) or sapphire, but the selection of the materials may be determined according to a wafer bonding method.

For example, in the case of bonding at room temperature through a surface activation process (surface activated bonding), wafers of different materials such as silicon (Si) or sapphire may be selected regardless of the thermal expansion coefficient. However, when wafer bonding between the growth wafer G, the support wafer S, and the back wafer 140, bonding may be performed at a temperature of 50° C. or higher, or when annealing at a temperature of 50° C. or higher without removing one wafer while bonding between wafers is performed, wafers of the same material need to be selected.

Meanwhile, in the above-described manufacturing process of the front wafer 110, before the ohmic contact electrode 124 is formed on the surface of the first semiconductor region 1201 or the surface of the second semiconductor region 1202, in the case where the surface of the first semiconductor region 1201 is exposed (p-side up form) or the surface of the second semiconductor region 1202 is exposed (n-side up form), the surfaces may be polished and smoothly planarized through mechanical polishing (MP) or chemical-mechanical polishing (CMP) so as to have a smooth surface.

In addition, the ohmic contact electrode 124 of the front wafer 110 is formed of a material having transparent conductivity. When the ohmic contact electrode 124 is formed to be in contact with the first semiconductor region 1201 which is a p-type semiconductor, the material of the ohmic contact electrode 124 may include NiO, PtO, PdO, AgO2, Au, Rh2O3, RuO2, In2O3, SnO2, ZnO, IZO, ITO, and IGZO. When the ohmic contact electrode 124 is formed to be in contact with the second semiconductor region 1202 which is an n-type semiconductor, the material of the ohmic contact electrode 124 may include TiN, CrN, VN, In2O3, SnO2, ZnO, IZO, ITO, and IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a chemical-mechanical polishing (CMP) process for polishing and flattening the surface of the second semiconductor region 1202 before forming the ohmic contact electrode 124 having transparent conductivity.

Additionally, the surface of the ohmic contact electrode 124 formed on the front wafer 110 may also be polished and smoothed through mechanical polishing (MP) or chemical-mechanical polishing (CMP).

Meanwhile, when manufacturing a vertically stacked microdisplay panel 100 provided with a positive common electrode, the third front wafer 113 may have an n-side up form, the second front wafer 112 may have a p-side up form, and the first front wafer 111 may have a p-side up form. However, when manufacturing a vertically stacked microdisplay panel 100 provided with a negative common electrode, the third front wafer 113 may have a p-side up form, the second front wafer 112 may have an n-side up form, and the first front wafer 111 may have an n-side up form. However, it goes without saying that the form of each front wafer 110 may vary depending on the stacking order of the light-emitting portion 120.

The back wafer 140 is an active driving IC driven by an active matrix (AM) method, and refers to a CMOS wafer in which a plurality of CMOS electrode pads 141 are arranged on an upper surface in an array, as shown in FIG. 8. A passivation layer may be formed on an upper surface of the back wafer 140 so that upper surfaces of the plurality of CMOS electrode pads 141 are not exposed, and a portion of the passivation layer may be etched so that the plurality of CMOS electrode pads 141 are exposed when the front wafer 110 is bonded.

Here, the back wafer 140 may be prepared as a Si wafer having a (100) crystal plane, and may be prepared as an 8-inch or 12-inch Si wafer according to a standard CMOS IC process. However, considering that a typical LED wafer (front wafer 110) for bonding is 4 inches or 6 inches, the size of the back wafer is not particularly limited.

The stacking step S120 is a step of vertically stacking the plurality of light-emitting portions 120 on the support wafer S by repeatedly bonding another front wafer 110 on one front wafer 110 through the bonding layer 130 and then removing the support wafer S of the other front wafer 110.

Here, the bonding layer 130 may be formed of a ceramic material that is optically transparent and electrically conductive, that is, has transparent conductivity. Here, optically transparent means transparent (a transmittance of 80% or more) or translucent (semitransparent with a transmittance of 50% or more) within the wavelength range of light (including visible light) used in an optical exposure (photolithography) process, and electrically conductive means having an electrical resistance of less than 10-3 Ω/cm. The ceramic materials having transparent conductivity may include a transparent conductive oxide (TCO), a transparent conductive nitride (TCN), and a transparent conductive oxide nitride (TCON).

In this case, when the ceramic material is a transparent conductive oxide, the ceramic material may include In203, SnO2, ZnO, IZO, ITO, and IGZO, when the ceramic material is a transparent conductive nitride, the ceramic material may include TiN, CrN, and VN, and when the ceramic material is a transparent conductive oxide nitride, the ceramic material may include InON, SnON, ZnON, IZON, ITON, and IGZON.

As shown in FIG. 9, for example, in the stacking step S120, first, the second front wafer 112 in a p-side up form that emits green light may be bonded to the third front wafer 113 in an n-side up form that emits blue light through a bonding layer 130, and then the support wafer S of the second front wafer 112 may be removed using laser lift-off or the like. Afterward, the second semiconductor region 1202 of the second light-emitting portion 122 exposed by removing the support wafer S may be etched to reduce its thickness, and then an n-type ohmic contact electrode 124 may be formed on the surface of the second semiconductor region 1202, and a bonding layer 130 may be deposited on the n-type ohmic contact electrode 124.

Subsequently, the first front wafer 111 in a p-side up form that emits red light may be bonded through the bonding layer 130, and then the support wafer S of the first front wafer 111 may be removed using chemical lift-off or the like. Afterward, the second semiconductor region 1202 of the first light-emitting portion 121 exposed by removing the support wafer S may be etched to reduce its thickness, and then an n-type ohmic contact electrode 124 may be formed on the surface of the second semiconductor region 1202.

Subsequently, heat treatment should be performed at a high temperature of 200 to 900° C. to improve the bonding strength of the transparent conductive ceramic bonding layer 130. That is, in the present invention, after all the RGB light sources are stacked on the support wafer S, high-temperature heat treatment may be performed to secure the bonding strength between the RGB epitaxial layers, and then the RGB stacked structure may be bonded to the CMOS Si back wafer 140 at one time.

Through this, the support wafer S, the bonding layer B, the third light-emitting portion 123 having the ohmic contact electrode 124 formed on each of the upper and lower surfaces, the bonding layer 130, the second light-emitting portion 122 having the ohmic contact electrode 124 formed on each of the upper and lower surfaces, the bonding layer 130, and the first light-emitting portion 121 having the ohmic contact electrode 124 formed on each of the upper and lower surfaces may be stacked in the vertical direction, and the stack secures strong bonding strength between the RGB epitaxial layers through heat treatment at high temperature.

However, the present invention is not limited to this stacking order, and the first light-emitting portion 121, the second light-emitting portion 122, and the third light-emitting portion 123 may be stacked in the vertical direction in the same manner, and various combinations, such as stacking the second light-emitting portion 122, the first light-emitting portion 121, and the third light-emitting portion 123 in this order, are possible.

Meanwhile, the stacking step S120 may utilize the property of smooth surfaces sticking to each other due to van der Waals forces without using high pressure or an external electric field. Accordingly, it is preferable to introduce a chemical-mechanical polishing (CMP) process before bonding the front wafers 110 to each other so that the roughness of each bonding surface is very low (Rq, <0.5 nm @2 μm×2 μm) and there are no particles such as impurities between the surfaces. To this end, in the stacking step S120, before bonding the front wafers 110 to each other, the surface of the bonding layer 130 of the front wafers 110 may be polished to a smooth flat surface through mechanical polishing (MP) or chemical-mechanical polishing (CMP).

The first processing step S130 is a step of forming a reflective layer 190 on one side of a plurality of stacked light-emitting portions 120, for example, on the n-type ohmic contact electrode 124 of the first light-emitting portion 121, and then forming a first short passage 181 in a partial region from one side of the reflective layer 190.

Hereinafter, an example in which the light-emitting portions 120 are stacked in the order of the third light-emitting portion 123, the second light-emitting portion 122, and the first light-emitting portion 121 is described, but as described above, the stacking order of the light-emitting portions 120 may be different.

In the first processing step S130, the reflective layer 190 may be first formed on the first light-emitting portion 121, and then contact holes are formed in the regions where a first LED stack L1 to a third LED stack L3 are to be formed. In this case, the reflective layer 190 may be formed of a non-conductive reflector, and may be formed of, for example, a distributed Bragg reflector (DBR), an omni-directional reflector (ODR), an oxide-metal-oxide (OMO), or the like, but is not limited thereto.

Subsequently, in the first processing step S130, a through hole may be formed to extend from the contact hole in the region where the third LED stack L3 is to be formed to pass through the reflective layer 190, the first light-emitting portion 121, the ohmic contact electrode 124 on each of the upper and lower surfaces of the first light-emitting portion 121, and the bonding layer 130 below the first light-emitting portion 121, and then pass through the second light-emitting portion 122. In this case, the through hole may be formed to the ohmic contact electrode 124 on the lower surface of the second light-emitting portion 122 or to the bonding layer 130 below the second light-emitting portion 122, but is not limited thereto.

Additionally, in the first processing step S130, a through hole may be formed to extend from the contact hole in the region where the second LED stack L2 is to be formed to pass through the reflective layer 190 and the first light-emitting portion 121. In this case, the through hole may be formed to the ohmic contact electrode 124 on the lower surface of the first light-emitting portion 121 or to the bonding layer 130 below the first light-emitting portion 121, but is not limited thereto.

Additionally, in the first processing step S130, a through hole may be formed to extend from the contact hole in the region where the first LED stack L1 is to be formed to pass through the reflective layer 190. Meanwhile, when a depth of the contact hole is formed to pass through the reflective layer 190, the contact hole may be a through hole.

Afterward, in the first processing step S130, the formed through hole may be filled with an optically transparent and electrically conductive transmissive material to form the first short passage 181. In addition, in the present invention, a width of the first short passage 181 is not particularly limited.

Here, forming the short passage 180 (including the first short passage 181 and a second short passage 182 that is described below) after forming the through hole may be forming a short passage 180 by filling the through hole with a conductive transmissive material in a direct self-align manner, or by filling the through hole with a conductive transmissive material in a liquid coating manner such as sol-gel, but is not limited thereto, and any method that can form the short passage 180 in the through hole may be used.

Meanwhile, in the first processing step S130 of the present invention, when filling the through hole with a conductive transparent material to form the first short passage 181, after filling the through hole, the material may remain on the surface of the reflective layer 190 or may be removed. In this case, when the material remains on the reflective layer 190, a transmissive layer 170 may be formed. That is, both the first short passage 181 and the transmissive layer 170 may be formed of an optically transparent and electrically conductive material.

When the short passage 180 and the transmissive layer 170 are formed of an optically transparent and electrically conductive material, it is preferable to form the short passage 180 and the transmissive layer 170 using a material having low resistance and high transmittance characteristics. These materials may include, but are not limited to, In2O3, SnO2, ZnO, IZO, ITO, and IGZO.

The bonding step S140 is a step in which, after the first processing step S130, the support wafer S having the plurality of light-emitting portions 120 and the reflective layer 190 stacked in the vertical direction is bonded to the back wafer 140 through the bonding layer 130, and then the support wafer S is removed.

After the support wafer S and the back wafer 140 are bonded, heat treatment of the bonding layer 130 should be performed at a temperature that does not damage a CMOS circuit of the back wafer 140, and the removal of the support wafer S may be performed using techniques such as mechanical polishing (MP) and chemical lift off (CLO). Meanwhile, when a sapphire support wafer S is used as the support wafer S, it is of course possible to remove the support wafer S using a laser lift off (LLO) technique.

Accordingly, when using the third front wafer 113 in an n-side up form, the second front wafer 112 in a p-side up form, and the first front wafer 111 in a p-side up form, the first light-emitting portion 121 emitting red light, the second light-emitting portion 122 emitting green light, and the third light-emitting portion 123 emitting blue light may be sequentially stacked in a p-side up form on the back wafer 140. However, the stacking order of the light-emitting portions 120 is not limited thereto.

In addition, when using the third front wafer 113 in a p-side up form, the second front wafer 112 in an n-side up form, and the first front wafer 111 in an n-side up form, the first light-emitting portion 121 emitting red light, the second light-emitting portion 122 emitting green light, and the third light-emitting portion 123 emitting blue light may be sequentially stacked in an n-side up form on the back wafer 140. However, the stacking order of the light-emitting portions 120 is not limited thereto.

Meanwhile, when the light-emitting portions 120 are stacked in an n-side up form, after the support wafer S of the third light-emitting portion 123 is removed, the second semiconductor region 1202 of the third light-emitting portion 123 may be exposed. In addition, in the bonding step S140, after reducing the thickness of the second semiconductor region 1202 of the third light-emitting portion 123, a surface texturing process may be optionally performed on a surface of the second semiconductor region 1202, and then the n-type ohmic contact electrode 124 may be formed on the surface-textured surface of the second semiconductor region 1202.

The second processing step S150 is a step of forming a second short passage 182 from the other side (for example, the third light-emitting portion 123 side) of the plurality of stacked light-emitting portions 120.

Specifically, in the second processing step S150, a through hole may be formed to extend in the region where a first LED stack L1 is to be formed to pass through the third light-emitting portion 123, the ohmic contact electrodes 124 on the upper and lower surfaces of the third light-emitting portion 123, and the bonding layer 130 below the third light-emitting portion 123, and then pass through the second light-emitting portion 122. In this case, the through hole may be formed to the ohmic contact electrode 124 on the lower surface of the second light-emitting portion 122 or to the bonding layer 130 below the second light-emitting portion 122, but is not limited thereto.

Additionally, in the second processing step S150, a through hole may be formed to extend in the region where a second LED stack L2 is to be formed to pass through the third light-emitting portion 123. In this case, the through hole may be formed to the ohmic contact electrode 124 on the lower surface of the third light-emitting portion 123 or to the bonding layer 130 below the third light-emitting portion 123, but is not limited thereto.

Afterward, in the second processing step S150, the formed through hole may be filled with an optically transparent and electrically conductive transmissive material to form the second short passage 182. In addition, in the present invention, a width of the second short passage 182 is not particularly limited.

Meanwhile, in the second processing step S150 of the present invention, when filling the through hole with a conductive transmissive material to form the second short passage 182, after filling the through hole, the material may remain on the surface of the p-type ohmic contact electrode 124 of the third semiconductor 123 or may be removed. In this case, when the material remains on the surface of the p-type ohmic contact electrode 124 of the third semiconductor 123, a transmissive layer 170 may be formed. That is, both the second short passage 182 and the transmissive layer 170 may be formed of an optically transparent and electrically conductive material.

The etching step S160 is a step in which the plurality of light-emitting portions 120, the ohmic contact electrode 124, the bonding layer 130, the transmissive layer 170, and the reflective layer 190 which have been stacked are separated into preset units by etching, thereby allowing the plurality of LED stacks L to be respectively disposed and aligned on the plurality of CMOS electrode pads 141.

That is, the etching step S160 is a step which vertically etches the light-emitting portion 120, the ohmic contact electrodes 124, the bonding layers 130, the transmissive layer 170, and the reflective layer 190 until the surface or adjacent region of the back wafer 140 is exposed so that the array is formed, that is, the plurality of LED stacks L are aligned on upper portions of the aligned CMOS electrode pads 141. Here, the preset unit may mean a pixel or sub-pixel unit, and may mean the width (diameter) of the plurality of LED stacks L.

In this case, since both the bonding layer 130 and the ohmic contact electrode 124 of the present invention are made of a ceramic material rather than metals, there is an advantage in that etching is easy in a plasma dry process and there is no problem in that etching byproducts are redeposited.

Meanwhile, the plurality of LED stacks L may include a first LED stack L1 for emitting only a first color, a second LED stack L2 for emitting only a second color, and a third LED stack L3 for emitting only a third color.

After the above-described etching step S160 has been performed, the first LED stack L1 to the third LED stack L3 disposed on the CMOS electrode pads 141 may have a structure in which a bonding layer 130, a transmissive layer 170, a reflective layer 190, a first layer, a bonding layer 130, a second layer, a bonding layer 130, a third layer, and a transmissive layer 170 are sequentially stacked. Here, the first layer may be a first light-emitting portion 121 having ohmic contact electrodes 124 formed on the upper and lower surfaces, the second layer may be a second light-emitting portion 122 having ohmic contact electrodes 124 formed on the upper and lower surfaces, and the third layer may be a third light-emitting portion 123 having ohmic contact electrodes 124 formed on the upper and lower surfaces, but as described above, the stacking order of the light-emitting portions 120 may vary.

Additionally, a first short passage 181 may be formed in the first LED stack L1 to pass through the reflective layer 190 from the transmissive layer 170 at the bottom. Additionally, a second short passage 182 may be formed in the first LED stack L1 to pass through the third layer and the bonding layer 130 below the third layer from the transmissive layer 170 at the top, and then pass through the second layer. In this case, the second short passage 182 may be formed to the lower ohmic contact electrode 124 of the second layer or to the bonding layer 130 below the second layer, but is not limited thereto.

Accordingly, the first LED stack L1 may emit light of a corresponding color by allowing a current to flow only through the first layer (for example, by allowing a current to flow only through the first light-emitting portion 121 to emit only a first color), and the emitted light may be reflected by the reflective layer 190 without optical loss and emitted to the outside.

Additionally, a first short passage 181 may be formed in the second LED stack L2 to pass through the reflective layer 190 and the first layer from the transmissive layer 170 at the bottom. In this case, the first short passage 181 may be formed to the upper ohmic contact electrode 124 of the first layer or to the bonding layer 130 above the first layer, but is not limited thereto. Additionally, a second short passage 182 may be formed in the second LED stack L2 to pass through the third layer from the transmissive layer 170 at the top. In this case, the second short passage 182 may be formed to the lower ohmic contact electrode 124 of the third layer or to the bonding layer 130 below the third layer, but is not limited thereto.

Accordingly, the second LED stack L2 may only emit light of a corresponding color by allowing a current to flow only through the second layer (for example, only the second color may be emitted by allowing a current to flow only through the second light-emitting portion 122), and the emitted light may be reflected by the reflective layer 190 without optical loss and emitted to the outside.

Additionally, in the third LED stack L3, a first short passage 181 may be formed to pass through the reflective layer 190, the first layer, and the bonding layer 130 above the first layer from the transmissive layer 170 at the bottom, and then pass through the second layer. In this case, the first short passage 181 may be formed to the upper ohmic contact electrode 124 of the second layer or to the bonding layer 130 above the second layer, but is not limited thereto. Additionally, a separate second short passage 182 may not be formed in the third LED stack L3.

Accordingly, the third LED stack L3 may only emit light of a corresponding color by allowing a current to flow only through the third layer, and the light emitted from the third layer may be reflected by the reflective layer 190 without optical loss and emitted to the outside.

In addition, the light-emitting portions 120 of each LED stack L may be stacked in a p-side up form or an n-side up form depending on the form of the front wafer 110, and the structure of each LED stack L may vary depending on the stacking order of the light-emitting portions 120, as described above.

Accordingly, the optical loss due to the CMOS electrode pads in the vertically stacked tandem structure can be significantly improved.

Meanwhile, in the present invention, the light-emitting areas of the plurality of LED stacks L may all be the same, and the operating voltages may also all be set to be the same for the plurality of LED stacks L. Typically, each of the light-emitting portions 120 that emits red, green or blue may not have the same operating voltage. However, assuming that the operating voltage of each of the light-emitting portions 120 is 3 V, although the present invention has a stacked structure, since all serial connections are disconnected by conducting current through the short passage 180, it becomes the same as a parallel structure, and thus the operating voltages may all be set to the same 3 V.

The forming step S170 is a step of forming a mold portion 150 that fills the space between the plurality of aligned LED stacks L, and then forming a common electrode 160 on the plurality of LED stacks L. In this case, when the light-emitting portions 120 are in a p-side up form, the common electrode 160 may be formed as a positive electrode, and when the light-emitting portions 120 are in an n-side up form, the common electrode 160 may be formed as a negative electrode.

In this case, preferably, before forming the mold portion 150 that fills the space between the plurality of aligned LED stacks L, a passivation process, that is, a process of covering the side surfaces of all light-emitting portions 120 with an optically transparent and electrically insulating material (for example, SiO2, SiNx, or A12O3), may be performed.

More specifically, in the forming step S170, a mold portion 150 may be formed between and above the plurality of aligned LED stacks L, the mold portion 150 may be etched so that upper portions of the plurality of LED stacks L are exposed, and then the common electrode 160 may be formed to be in contact with the upper portions of the plurality of LED stacks L, thereby completing the vertically stacked LEDOS structure. Here, the common electrode 160 may be formed of a material having transparent conductivity similar to the ohmic contact electrode 124, and when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO.

Additionally, the surface of the common electrode 160 may also be polished to a smooth flat surface through mechanical polishing (MP) or chemical-mechanical polishing (CMP).

Furthermore, although not shown, a protective layer made of a transparent organic material may be additionally formed to protect the common electrode 160 from the atmospheric environment.

Hereinafter, a vertically stacked microdisplay panel 100 according to one embodiment of the present invention will be described in detail with reference to the attached drawings.

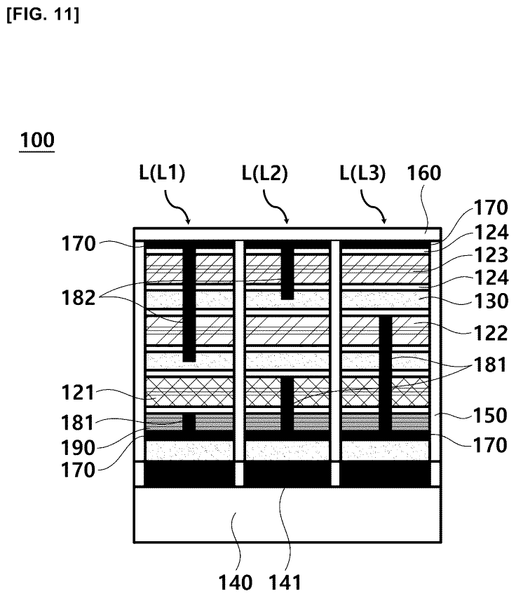

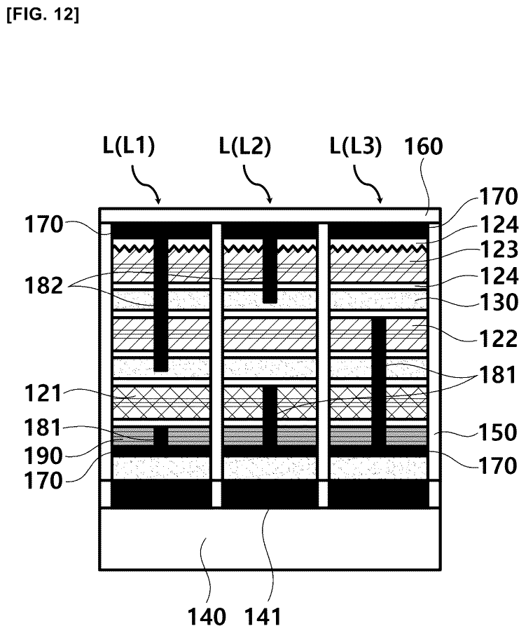

FIGS. 11 and 12 show a vertically stacked microdisplay panel according to one embodiment of the present invention.

As shown in FIG. 11, the vertically stacked microdisplay panel 100 according to one embodiment of the present invention may include a back wafer 140, a plurality of LED stacks L, a mold portion 150, and a common electrode 160.

Hereinafter, some of the overlapping content with the method S100 of manufacturing a vertically stacked microdisplay panel according to one embodiment of the present invention will be omitted.

The back wafer 140 is an active driving IC driven by an active matrix (AM) method, and refers to a CMOS wafer in which a plurality of CMOS electrode pads 141 are arranged on an upper surface in an array. A passivation layer may be formed on an upper surface of the back wafer 140, and a portion of the passivation layer may be etched so that the plurality of CMOS electrode pads 141 are exposed when bonding a front wafer 110.

The plurality of LED stacks L may each include a plurality of light-emitting portions 120 having ohmic contact electrodes 124 on the upper and lower surfaces, which are vertically stacked through bonding layers 130, and may be respectively aligned on the plurality of CMOS electrode pads 141.

Specifically, the plurality of LED stacks L may include a first LED stack L1 for emitting only a first color, a second LED stack L2 for emitting only a second color, and a third LED stack L3 for emitting only a third color.

Here, the first LED stack L1 to the third LED stack L3 disposed on the CMOS electrode pad 141 may have a structure in which a bonding layer 130, a transmissive layer 170, a reflective layer 190, a first layer, a bonding layer 130, a second layer, a bonding layer 130, a third layer, and a transmissive layer 170 are sequentially stacked. Here, the first layer may be a first light-emitting portion 121 having ohmic contact electrodes 124 formed on the upper and lower surfaces, the second layer may be a second light-emitting portion 122 having ohmic contact electrodes 124 formed on the upper and lower surfaces, and the third layer may be a third light-emitting portion 123 having ohmic contact electrodes 124 formed on the upper and lower surfaces, but as described above, the stacking order of the light-emitting portions 120 may vary.

Additionally, a first short passage 181 may be formed in the first LED stack L1 to pass through the reflective layer 190 from the transmissive layer 170 at the bottom. Additionally, a second short passage 182 may be formed in the first LED stack L1 to pass through the third layer and the bonding layer 130 below the third layer from the transmissive layer 170 at the top, and then pass through the second layer. In this case, the second short passage 182 may be formed to the lower ohmic contact electrode 124 of the second layer or to the bonding layer 130 below the second layer, but is not limited thereto.

Accordingly, the first LED stack L1 may emit light of a corresponding color by allowing a current to flow only through the first layer (for example, by allowing a current to flow only through the first light-emitting portion 121 to emit only a first color), and the emitted light may be reflected by the reflective layer 190 without optical loss and emitted to the outside.

Additionally, a first short passage 181 may be formed in the second LED stack L2 to pass through the reflective layer 190 and the first layer from the transmissive layer 170 at the bottom. In this case, the first short passage 181 may be formed to the upper ohmic contact electrode 124 of the first layer or to the bonding layer 130 above the first layer, but is not limited thereto. Additionally, a second short passage 182 may be formed in the second LED stack L2 to pass through the third layer from the transmissive layer 170 at the top. In this case, the second short passage 182 may be formed to the lower ohmic contact electrode 124 of the third layer or to the bonding layer 130 below the third layer, but is not limited thereto.

Accordingly, the second LED stack L2 may only emit light of a corresponding color by allowing a current to flow only through the second layer (for example, only the second color may be emitted by allowing a current to flow only through the second light-emitting portion 122), and the emitted light may be reflected by the reflective layer 190 without optical loss and emitted to the outside.

Additionally, a first short passage 181 may be formed in the third LED stack L3 to pass through the reflective layer 190, the first layer, and the bonding layer 130 above the first layer from the transmissive layer 170 at the bottom, and then pass through the second layer. In this case, the first short passage 181 may be formed to the upper ohmic contact electrode 124 of the second layer or to the bonding layer 130 above the second layer, but is not limited thereto. Additionally, a separate second short passage 182 may not be formed in the third LED stack L3.

Accordingly, the third LED stack L3 may only emit light of a corresponding color by allowing a current to flow only through the third layer, and the light emitted from the third layer may be reflected by the reflective layer 190 without optical loss and emitted to the outside.

In addition, the light-emitting portions 120 of each LED stack L may be stacked in a p-side up form or an n-side up form, and when the third light-emitting portion 123 is disposed in an n-side up form on the uppermost layer as shown in FIG. 12, an upper surface of the third light-emitting portion 123 may be surface-textured to improve light extraction efficiency.

Meanwhile, the present invention is not limited to the stacking order of the light-emitting portion 120, and as described above, the structure of each LED stack L may vary depending on the stacking order of other light-emitting portions 120.

Accordingly, the optical loss due to the CMOS electrode pads in the vertically stacked tandem structure can be significantly improved.

The mold portion 150 supports the vertically stacked LEDOS structure and may be formed to fill the space between the plurality of aligned LED stacks L.

In the present invention, the light-emitting portions 120 of the LED stack L may be stacked in a p-side up form or an n-side up form, and accordingly, the common electrode 160 may be formed as a positive electrode or a negative electrode and may be formed on the plurality of LED stacks L on which the mold portion 150 is formed. Here, when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO.

According to the present invention, since a color filter is unnecessary despite the adoption of a vertically stacked tandem structure, the color quality of a microdisplay can be significantly improved, and process complexity and productivity can be significantly improved.

Also, according to the present invention, unlike the existing monolithic integration method or hybridization method in which there are alignment issues, an engineering monolithic epitaxy wafer is first manufactured, and then a stack on the engineering monolithic epitaxy wafer is etched to separate the stack into preset units, thereby allowing a plurality of LED stacks to be aligned on a plurality of CMOS electrode pads. Thus, not only a small-diameter wafer of 6 inches or less but also a large-diameter wafer of 8 inches or more can be used so that the product yield can be significantly increased.

Furthermore, according to the present invention, since a bonding layer and an ohmic contact electrode are made of an electrically conductive transparent ceramic material rather than metals, the possibility of an electrical short-circuit failure is significantly reduced, and the reliability of the device is greatly increased. In addition, there is the effect of easily performing etching in a plasma dry process for LED stack alignment while eliminating the problem of etch byproduct redeposition. Furthermore, the above-described ease of etching offers significant advantages in the production of high-resolution microdisplays with ultra-fine pixels less than 3 μm.

Moreover, according to the present invention, a light-emitting portion, a bonding layer, and an ohmic contact electrode are all transparent, allowing visible light to pass therethrough, thereby eliminating alignment errors during the exposure process.

In addition, according to the present invention, optical loss due to CMOS electrode pads in a vertically stacked tandem structure can be significantly improved.

Meanwhile, the effects of the present invention are not limited to the above-described effects, and various other effects may be included within a scope apparent to those skilled in the art from the description below.

Although all components constituting the embodiments of the present invention have been described as being combined or operating in combination as one, the present invention is not necessarily limited to such embodiments. That is, all of the components may be selectively combined and operated in one or more combinations within the scope of the present invention.

Furthermore, terms such as “comprise,” “include,” or “have” described above, unless specifically stated otherwise, imply that the corresponding component may be present, and therefore should be interpreted to include other components rather than excluding other components. All terms, including technical or scientific terms, have the same meaning as commonly understood by a person of ordinary skill in the art to which the present invention pertains, unless otherwise defined. Commonly used terms, such as terms defined in dictionaries, should be interpreted to be consistent with the contextual meaning of the related art, and shall not be interpreted in an ideal or overly formal sense, unless explicitly defined in the present invention.

Further, the above description is merely an example of the technical idea of the present invention, and those skilled in the art will appreciate that various modifications and variations can be made without departing from the essential characteristics of the present invention.

Accordingly, the embodiments disclosed in the present invention are intended to illustrate, rather than limit, the technical concept of the present invention, and the scope of the technical concept of the present invention is not limited by these embodiments. The scope of protection of the present invention should be interpreted by the following claims, and all technical concepts within the scope equivalent thereto should be construed as being included within the scope of the present invention.

What is claimed is:

1. A vertically stacked microdisplay panel comprising:
a back wafer having a plurality of complementary metal-oxide semiconductor (CMOS) electrode pads aligned on an upper surface;
a plurality of light-emitting diode (LED) stacks each including a plurality of light-emitting portions stacked in a vertical direction through a bonding layer, and respectively aligned on the plurality of CMOS electrode pads; and
a common electrode formed on the plurality of LED stacks,
wherein each of the plurality of LED stacks has a short passage formed in a partial region so that a current flows through the light-emitting portion where the short passage is not formed, and only a specific color is emitted, and
a reflective layer is disposed between the light-emitting portion and the CMOS electrode pad.

2. The vertically stacked microdisplay panel of claim 1, wherein the reflective layer is formed of a non-conductive reflector.

3. The vertically stacked microdisplay panel of claim 2, wherein the short passage is formed to pass through the reflective layer.

4. The vertically stacked microdisplay panel of claim 1, wherein the common electrode is a positive electrode or a negative electrode.

5. A method of manufacturing a vertically stacked microdisplay panel, comprising:
a preparation step of preparing a plurality of front wafers including a support wafer and light-emitting portions, and a back wafer having a plurality of CMOS electrode pads aligned on an upper surface;
a stacking step of vertically stacking the plurality of light-emitting portions on the support wafer by repeatedly bonding another front wafer on one front wafer through a bonding layer and then removing the support wafer of the other front wafer;
a first processing step of forming a reflective layer on one side of the plurality of stacked light-emitting portions, and then forming a first short passage in a partial region from one side of the reflective layer;
a bonding step of bonding the plurality of stacked light-emitting portions to the back wafer, and then removing the support wafer to stack the plurality of light-emitting portions on the back wafer;
a second processing step of forming a second short passage in a partial region from the other side of the plurality of stacked light-emitting portions;
an etching step of etching the plurality of stacked light-emitting portions and separating the plurality of stacked light-emitting portions into preset units, thereby allowing the plurality of LED stacks to be respectively aligned on the plurality of CMOS electrode pads; and
a forming step of forming a common electrode on the plurality of LED stacks,
wherein each of the plurality of LED stacks has a short passage formed in a partial region so that a current flows through the light-emitting portion where the short passage is not formed, and only a specific color is emitted, and
the reflective layer is between the light-emitting portion and the CMOS electrode pad.

6. The method of claim 5, wherein the reflective layer is formed of a non-conductive reflector.

7. The method of claim 6, wherein the first short passage is formed to pass through the reflective layer.

8. The method of claim 5, wherein the common electrode is a positive electrode or a negative electrode.
